(19) United States
(12) Patent Application Publication
(10) Pub. No.: US 2012/0193755 A1
(43) Pub. Date: Aug. 2, 2012

(54) COPPER-BASED METALLIZATION SYSTEM INCLUDING AN ALUMINUM-BASED TERMINAL LAYER

(75) Inventor: Alessandro Dundulachi, Vimercate (IT)

(73) Assignee: STMICROELECTRONICS S.R.L., Agrate Brianza (IT)

(21) Appl. No.: 13/351,396

(22) Filed: Jan. 17, 2012

(30) Foreign Application Priority Data
Feb. 1, 2011 (IT) VI2011A000015

(51) Int. Cl. H01L 21/768; H01L 23/62

(52) U.S. Cl. 257/529; 438/653; 438/601; 257/E23.149; 257/E21.584

(57) ABSTRACT

In a copper-based metallization system of a semiconductor device the contact pad, such as a bond pad, is formed on the basis of two lithography steps by depositing the cap metal layer stack directly on any exposed copper surface areas of the last metallization layer. After patterning of the cap layer stack therefore reliable confinement of any exposed metal region is accomplished on the basis of a conductive barrier material, while the actual passivation materials are formed and patterned subsequently, thereby avoiding any negative influence on these materials, as may be the case in some conventional approaches. Moreover, superior mechanical integrity of the contact pad in combination with superior electrical performance of any metal region in the last metallization layer is achieved.

PRIORITY CLAIM

This application claims priority from Italian Application for Patent No. VI2011A000015 filed Feb. 1, 2011, the disclosure of which is hereby incorporated by reference.

### TECHNICAL FIELD

Generally, the present invention relates to the technical field of semiconductor devices, and more particularly to the formation of copper-based metallization systems, in which contact pads such as bond pads and the like are provided on the basis of an aluminum comprising metal, which will be referred herein as cap metal or terminal metal layer.

### BACKGROUND

Generally, semiconductor devices are provided on appropriate carrier substrates including semiconductor regions in order to form semiconductor-based circuit elements, such as transistors, diodes, thyristors and the like. To this end, highly complex manufacturing techniques and process strategies have been developed in order to process semiconductor materials and dielectric materials for implementing the basic semiconductor-based circuit elements, which in turn are combined to more complex entities in order to implement the required electronic functionality. Generally, enhancing overall performance of complex semiconductor devices typically requires reduction of critical feature sizes, such as overall dimensions of transistors and the like, while also advanced manufacturing strategies and process techniques in combination with superior dielectric and conductive materials may contribute to the superior overall performance.

Due to the increasing number of active circuit elements and thus due to the increased packing density in and above the carrier substrate, typically the electrical connections between the individual semiconductor-based circuit elements may not be established in the same level, i.e. within and immediately above the semiconductor material used for forming the semiconductor-based circuit elements so that for this reason a metallization system has to be provided above the semiconductor material. To this end, well-established dielectric materials, for instance in the form of silicon dioxide, silicon nitride in combination with aluminum have been used as preferred materials for a metallization system. During the ongoing scaling of the semiconductor-based circuit elements, however, and also in view of further improving the overall performance of the semiconductor devices, increasingly semiconductor manufacturers are using a metal of superior conductivity and enhanced electromigration behavior compared to the well-established aluminum material. For example, copper has proven to be a viable candidate for enhancing the overall characteristics of a complex metallization system. Generally, upon forming a copper-based metallization system appropriate manufacturing strategies have to be applied due to copper's characteristic to readily diffuse in a plurality of established semiconductor materials and dielectric materials, such as silicon and silicon dioxide. Moreover, copper may not efficiently be deposited, i.e. at high deposition rates, on the basis of well-established physical and chemical vapor deposition techniques. Furthermore, it is very difficult to pattern copper on the basis of plasma assisted anisotropic etch techniques due to copper's lack of generating volatile etch by-products when applying well-established etch chemistries. For these reasons, so-called damascene or inlaid techniques are typically applied in order to form a copper-based metallization system.

To this end the metallization system may be formed, level by level, by providing an appropriate dielectric material or material system and patterning the dielectric material so as to receive trenches and openings, which are subsequently filled with a highly conductive copper comprising material by using electrochemical deposition techniques, such as electroplating and/or electroless plating. Furthermore, as indicated above, due to the high diffusion activity of copper in a plurality of well-established materials, such as silicon dioxide, a reliable copper confinement has to be ensured, which may be accomplished by embedding the copper material in a dielectric or conductive barrier material. For example, in frequently applied manufacturing strategies after patterning the dielectric material of a specific metallization layer, i.e. of a specific level of the metallization system including the dielectric material, i.e. a so-called inter-metal dielectric material comprising metal lines and vias embedded therein, a conductive barrier material or material system is deposited, for instance in the form of a tantalum nitride/tantalum bilayer, which is accomplished on the basis of well-established sputter deposition techniques and the like. Corresponding tantalum-based barrier material systems thus provide for superior adhesion of the copper material to the surrounding dielectric material and also suppress any unwanted out-diffusion of copper into the surrounding dielectric material. After applying the barrier material system, frequently a so-called seed layer, for instance a copper layer, is formed on the basis of sputter deposition and the like, followed by the actual deposition of the copper fill metal, which may be accomplished by electroplating, electroless plating or a combination thereof. Next, any excess material is removed, for instance by CMP (chemical mechanical polishing), thereby forming electrically isolated metal lines in the metallization layer under consideration. As a next step, typically a dielectric cap or etch stop layer is formed, for instance on the basis of a silicon nitride material, which has a pronounced copper diffusion blocking effect, thereby effecting a reliable copper confinement of exposed metal lines or generally metal regions of the metallization layer under consideration. Thereafter, a further metallization layer can be formed by depositing an appropriate dielectric material or material system and repeating the above-described process sequence for patterning the dielectric material and filling the corresponding openings with the barrier/copper material system as described above.

By providing copper material in the metallization system of complex semiconductor devices an overall superior performance may be obtained, since copper has higher electrical conductivity compared to aluminum so that copper-based metal lines having the same cross-sectional area as aluminum metal lines provide for higher drive current capability. In other words, overall dimensions of the metal lines may be reduced for a given drive current capability, thereby enabling an increased packing density in the metallization system. Furthermore, copper may generally provide for a superior electromigration behavior compared to aluminum due to the greater activation energy of copper compared to aluminum. Electromigration is to be understood as a phenomenon in which “material diffusion” is initiated at very high current densities by the directed flow of electrons. The current flow induced copper diffusion may thus result in a significant deterioration of the electrical performance of metal lines carrying high current densities, which may finally result in a total failure of the corresponding metal line. According to the presently established technical opinion the degree of copper diffusion in copper metal lines may significantly depend on the general presence of any diffusion paths in the metal line, i.e. the grain size and thus the number of grain boundaries and, in particular, on the presence of any interfaces formed by copper and a dielectric material, such as silicon nitride. For example, the interface formed by copper and the dielectric cap layer has been identified as a weak spot with respect to premature electromigration induced line failure. On the other hand, a plurality of conductive barrier materials such as tantalum, tantalum nitride provide for a strong interface to the copper material so that pronounced electromigration effects at the interface between the barrier material system and the actual copper fill metal are reduced.

Consequently, by using copper material instead of aluminum signal propagation delay and/or current drive capability and/or electromigration behavior may be enhanced compared to aluminum-based metallization systems. Consequently, in sophisticated semiconductor devices many or all of the metallization layers are typically formed on the basis of a copper material which, however, may require specific manufacturing strategies in forming appropriate contact pads, such as bond pads and the like, which act as an electric interface between the metallization system and a package which may finally accommodate the semiconductor chip. Typically, bond pads or generally contact pads for being contacted by wires and the like by applying well-established contact technologies are typically formed on the basis of well-established metal materials, such as an aluminum-based metal, which typically comprises a certain amount of copper. For example, a plurality of wire bonding techniques have been established which, however, may not be applied to copper-based contact pads due to the very different material characteristics of a substantially pure copper material compared to an aluminum/copper alloy that is typically used in conventional well-established contact technologies. Moreover, in addition to an appropriate terminal metal material or cap metal material also appropriate dielectric materials or passivation materials, for instance in the form of silicon dioxide, silicon nitride and the like, are provided so as to ensure proper mechanical and chemical integrity of the underlying metallization system.

### SUMMARY

A contact pad, such as a bond pad, is formed on the basis of two lithography steps by depositing the cap metal layer stack directly on any exposed copper surface areas of the last metallization layer. After patterning of the cap layer stack therefore reliable confinement of any exposed metal region is accomplished on the basis of a conductive barrier material, while the actual passivation materials are formed and patterned subsequently, thereby avoiding any negative influence on these materials, as may be the case in some conventional approaches.

According to one aspect there is provided a method of forming a metallization system of a semiconductor device. The method comprises forming a cap metal layer system directly on an exposed surface of a metal region of a last metallization layer wherein the metal region comprises copper. The method further comprises forming a contact pad from the cap metal layer system for the metal region. Additionally, a dielectric passivation layer is formed above the last metallization layer and the contact pad. Moreover, the dielectric passivation layer is patterned so as to expose at least a portion of the contact pad.

Consequently, according to this approach, the conductive materials for the contact pad, such as a bond pad, is applied prior to depositing any passivation material thereby enabling an appropriate confinement of any exposed copper surface areas by means of the cap metal layer system. Moreover, the patterning of the cap metal layer system may be performed with any appropriate over-etch time so as to reliably remove any conductive materials without being restricted by a material erosion of an underlying dielectric material. That is, since the actual passivation material is provided after the patterning of the cap metal layer system, any negative effects which may conventionally be associated with the metal patterning processes may be avoided. Moreover, the inventive method enables a very cost efficient overall manufacturing flow since two lithography processes may be sufficient for forming the contact pad.

In a further illustrative embodiment the cap metal layer system is formed so as to comprise at least one conductive barrier layer that is directly formed on the exposed surface of the metal region. Thus, an efficient copper confinement may be achieved.

In a further illustrative embodiment the step of forming the at least one conductive barrier layer comprises depositing a barrier material on the exposed surface area and on a dielectric material of the metallization layer. In this manner, well-established deposition techniques, such as sputter deposition, CVD and the like, may be applied thereby also contributing to a high degree of compatibility with conventional process strategies.

In a further illustrative embodiment, forming the at least one conductive barrier layer comprises performing a selective electrochemical deposition process. In this manner a desired conductive cap material, for instance an alloy comprising various components such as phosphorous, boron, molybdenum, nickel and the like may be applied in a highly selective manner by, for instance, electroless deposition techniques wherein exposed copper surface areas may efficiently be used as a catalyst material. Consequently, the subsequent patterning of the actual cap metal, such as an aluminum/copper alloy, may be accomplished with an etch sequence of reduced complexity, wherein the underlying dielectric material of the metallization layer may act as an efficient etch stop material.

In one preferred embodiment, the method further comprises forming a metal-based circuit element from the cap layer system wherein the circuit element is formed so as to be in contact with a second metal region that is formed in the last metallization layer. Due to the inventive method in which the cap metal layer system is deposited directly on any exposed surface areas, the patterning of the cap layer may be performed such that additional metal-based circuit elements such as resistors, electronic fuses and the like may be formed together with providing the contact pad. To this end, the corresponding lithography mask for patterning the cap metal layer provides a desired lateral size and shape of respective circuit elements, while the second metal region provides for an appropriate connection to any lower lying device levels. Consequently, additional circuit elements may be implemented in and above the metallization system without requiring any additional lithography steps.

In further illustrative embodiments, the process of forming the cap metal layer system comprises depositing at least an aluminum comprising metal layer above the metallization layer so as to cover each metal region of the last metallization layer and removing any conductive material from above at least a portion of the dielectric material of the last metallization layer so as to laterally isolate the metal regions. As discussed above, in this manner any metal regions of the last metallization layer may reliably be covered by the cap metal layer system, thereby providing for the desired copper confinement while at the same time a reliable electrical isolation of these regions in compliance with the overall circuit layout is ensured.

In a further illustrative embodiment, the removal of any conductive material from above at least a portion of the dielectric material comprises the step of performing an etch process and applying a specified over-etch time so as to etch into the dielectric material. In this manner, a reliable removal of any conductive material residue is ensured thereby avoiding or significantly reducing the probability of creating any leakage paths, while at the same time the actual passivation layer characteristics are not negatively influenced by the patterning of the cap metal layer system.

In other illustrative embodiments, only two lithography processes or less may be applied thereby providing for very cost effective overall manufacturing processes. Moreover, well-established cap layer systems, for instance comprising tantalum-based barrier layers, may be used so as to ensure a high degree of compatibility with conventionally used material systems.

According to a further aspect, a semiconductor device is provided. The device comprises last metallization layer that comprises an inter-metal dielectric material and a first metal region and a second metal region, wherein the first and second metal regions comprise copper and are laterally embedded in the inter-metal dielectric material. The semiconductor device further comprises a first cap metal layer stack formed above the first metal region so as to be in direct contact therewith. Additionally, the semiconductor device comprises a second cap metal layer stack formed above the second metal region so as to be in direct contact therewith. Additionally, the semiconductor device comprises a passivation layer stack that is formed laterally between the first and second cap metal layer stacks wherein the passivation layer stack covers the first metal region and exposes at least a portion of the second cap metal layer stack so as to form a contact pad.

As discussed above, the inventive semiconductor device comprises a contact pad that has superior mechanical integrity due to the lateral embedding into the passivation material. Moreover, the first and second metal regions may reliably be confined with respect to copper diffusion by the cap metal layer stack, irrespective of whether the corresponding cap metal layer stacks are used as contact pads or are covered by the passivation material.

In one illustrative embodiment the first cap metal layer stack is a passive circuit element such as a resistor, an electronic fuse and the like.

### BRIEF DESCRIPTION OF THE DRAWINGS

FIGS. 1a-1e illustrate process techniques in which a copper-based metallization system receives contact pads;

FIGS. 1f-1k illustrate process techniques in which a copper-based metallization system receives contact pads with a reduced number of process steps; and

FIGS. 2a-2f illustrate process techniques in which contact pad, such as a bond pad, is formed.

### DETAILED DESCRIPTION OF THE DRAWINGS

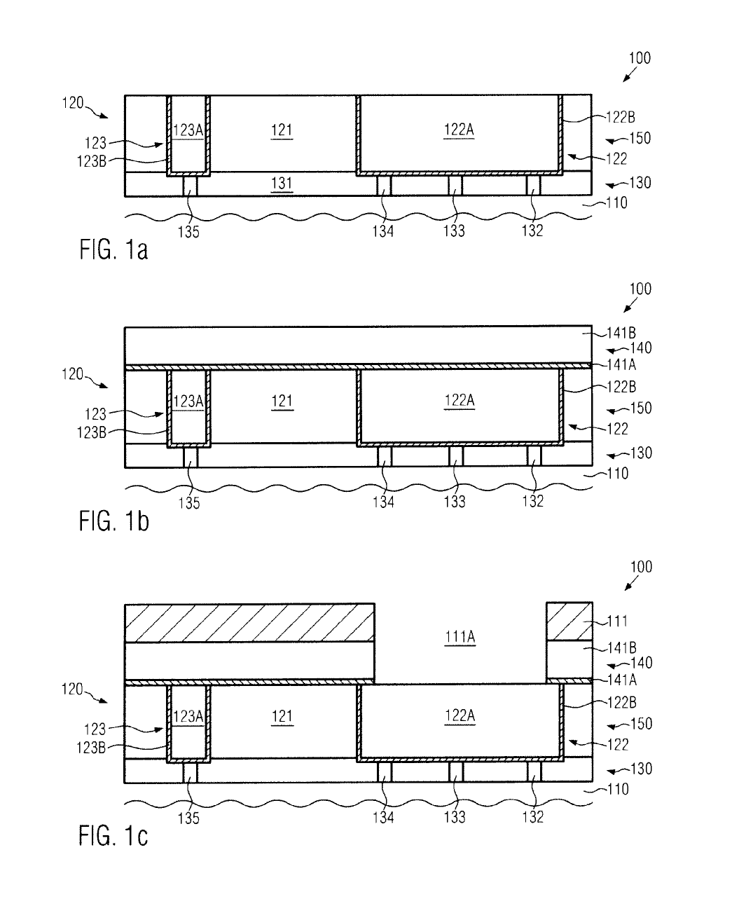

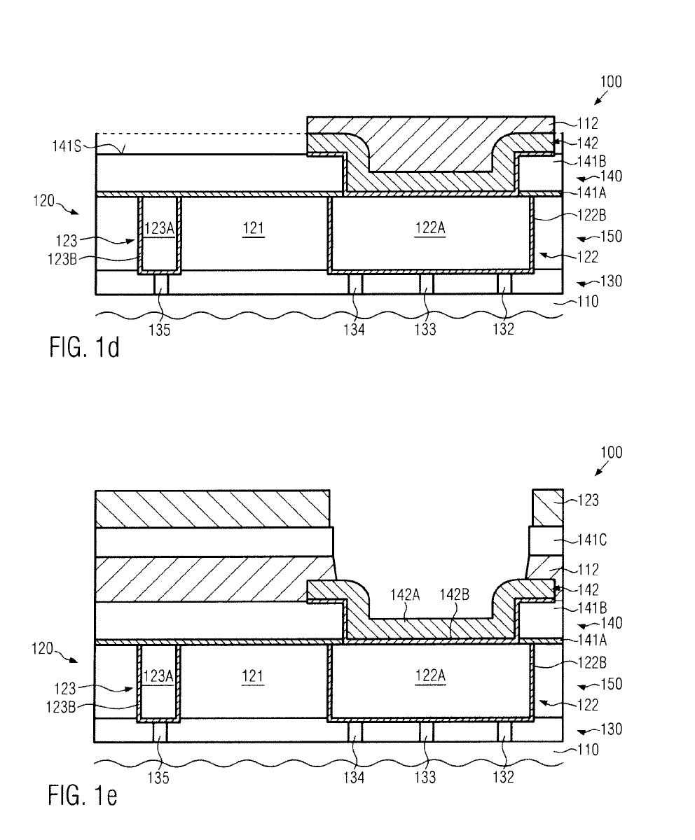

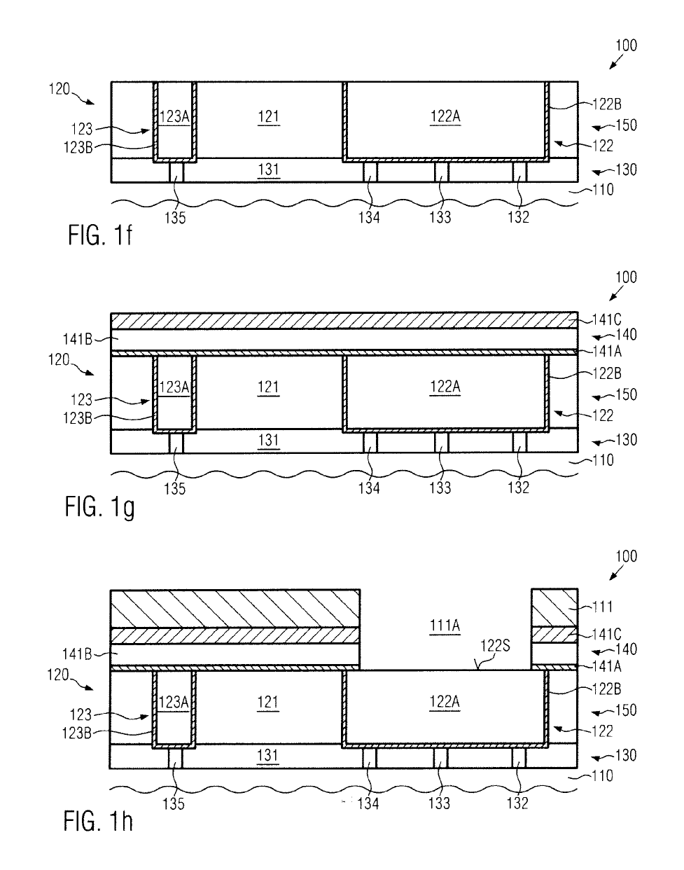

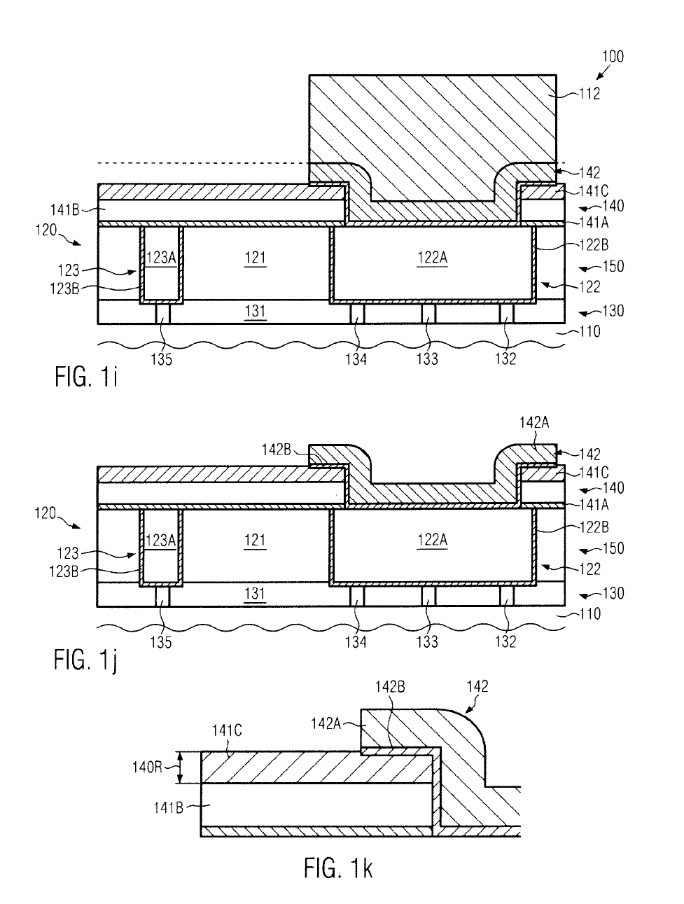

With reference to FIGS. 1a-1k various process techniques will now be described in more detail, in which a copper-based metallization system receives contact pads on the basis of a well-established aluminum-based cap metal.

FIG. 1a schematically illustrates a cross-sectional view of a semiconductor device 100 comprising a copper-based metallization system 150. The metallization system 150 is formed above an appropriate carrier material 110, which may also include semiconductor regions and layers as required for forming therein and thereabove semiconductor-based circuit elements, such as transistors, diodes, semiconductor-based resistors, capacitors and the like. For convenience, any such semiconductor-based circuit elements are not shown in FIG. 1a. The metallization system 150 comprises a metallization layer 120, which is to be understood as an appropriate dielectric material 121, such as a silicon dioxide material and the like, in combination with metal regions 122, 123 embedded therein. Moreover, a further metallization layer 130, or at least a portion thereof, is illustrated in FIG. 1a and may comprise an appropriate dielectric material 131 in combination with metal regions such as “vertical” contact elements 132, 135 so as to appropriately connect to the metal regions 122, 123, respectively. It should be appreciated that the metallization layer 130 may also be considered as a part of the metallization layer 120, depending on the overall process strategy to be applied. Generally, one or more additional metallization layers can be provided so as to finally connect to the semiconductor-based circuit elements formed in and above the carrier material 110. In the example shown, the metallization layer 120 represents the very last metallization layer, which in turn is to receive appropriate contact regions or contact pads for connecting to a package substrate and the like, for instance on the basis of wire bonding and the like.

The semiconductor device 100 as illustrated in FIG. 1a is formed on the basis of the following process strategy. After implementing any semiconductor-based circuit elements in and above the carrier material 110 by well-established manufacturing strategies, the metallization system 150 is formed level by level, for instance forming the metallization layer 130, which in the example shown actually represents an interface connecting a lower lying metallization layer (not shown) or semiconductor-based circuit elements with the metallization layer 120. To this end, the dielectric material 131 is applied by chemical vapor deposition (CVD) and the like, followed by a patterning process in which corresponding openings are formed, which are then filled with an appropriate material or material system as required for the vertical contacts 132-135. For example, frequently tungsten is used, possibly in combination with appropriate barrier materials such as titanium and titanium nitride, while in other cases copper may be used as a fill metal in combination with an appropriate barrier material (not shown in FIG. 1a). Thereafter, any excess material is removed, for instance by CMP, followed by the deposition of the dielectric material 121 of the metallization layer 120. For example, silicon dioxide is frequently used due to its reduced dielectric constant compared to silicon nitride material, which would provide for superior copper-confining characteristics, which however due to the increased dielectric constant may result in an increased parasitic capacitance. Thereafter, the dielectric material 121 is patterned by applying sophisticated lithography techniques and applying anisotropic plasma-based etch recipes in order to form openings extending through the dielectric material 121 with a size and shape as required for the metal regions 122, 123. Next, a conductive barrier material or material system 122b is deposited, for instance by sputter deposition and the like, as also previously discussed, followed by the deposition of a seed layer (not shown). Next, the fill metal 122a, 123a of the regions 122, 123 is deposited, for instance by electroplating and/or electroless plating. Finally, any excess material is removed by CMP thereby also removing any barrier material as required for providing the metal regions 122, 123 as isolated elements.

FIG. 1b schematically illustrates the device 100 with a passivation layer stack 140 formed above the metallization layer 120. The layer stack 140 comprises a silicon and nitrogen-containing dielectric material layer 141a, which acts as a copper-confining material due to the superior copper diffusion blocking capabilities of a silicon nitride-based material. Furthermore, the layer stack 140 comprises a second dielectric layer 141b, for instance in the form of silicon dioxide. The layers 140 are formed on the basis of well-established deposition techniques such as plasma enhanced CVD and the like.

FIG. 1c schematically illustrates the device 100 in a further advanced manufacturing stage in which an etch mask 111, such as a resist material and the like, is formed above the layer stack 140 in order to define the lateral position size and shape of a portion of the metal region 122 in order to form a contact pad thereon. To this end, the mask 111 comprises an appropriate mask opening 111a in order to expose the desired portion of the layer stack 140 to an appropriately selected etch atmosphere, which is established on the basis of appropriate plasma-based etch chemistries. Consequently, during the etch process the exposed portion of the material 141b and a corresponding portion of the material 141a are removed, thereby exposing a portion of the fill metal 122a.

FIG. 1d schematically illustrates the device 100 in a further advanced manufacturing stage. As illustrated, a contact region 142 is formed above the metal region 123 so as to be in direct contact therewith, wherein also a portion of the contact pad 142 is formed on the passivation layer 142b. To this end appropriate metal materials are deposited, for instance by sputter deposition, CVD and the like, for instance for forming an appropriate barrier material layer 142b, for instance in the form of a tantalum nitride/tantalum layer system thereby “re-confining” any exposed surface areas of the metal region 123. Thereafter, the desired aluminum-based cap material 142a is deposited. Next, an etch mask 112 is formed so as to define the final lateral dimensions of the contact region 142 and thereafter any appropriate etch process is applied so as to remove exposed portions of the materials 142b, 142a. During the etch process also a certain over-etch time or an additional etch phase can be applied in order to reliably remove any conductive material, which may also result in a certain material loss of the dielectric layer 141b. In order to provide a well-defined passivation material and also ensure mechanical integrity of the contact region 142 during the further processing, for instance in view of scratching the surface and the like, a final passivation material is typically provided above the material 141b so as to laterally enclose the contact pad 142.

FIG. 1e schematically illustrates the device 100 in a corresponding further advanced manufacturing stage. As shown, a further passivation material 141d, such as a silicon dioxide material, is formed above the layer 141b followed by a final passivation layer, for instance provided in the form of a silicon nitride material, as indicated by 141c. In order to re-expose at least a portion of the contact pad 142, a further etch mask 123 is formed by an appropriate lithography process and an appropriate etch technique is applied so as to etch through the materials 141c, 141d thereby finally exposing a portion of the contact region 142. Thus, after the removal of the etch mask 113 the contact pad 142 is laterally embedded in a portion of the passivation layer stack 140, which also has an appropriate size and a final layer with a well-defined thickness.

Consequently, upon performing three lithography steps involving the etch masks 111, 112 and 123, the passivation layer stack 140 can be provided with well defined surface characteristics, while at the same time a desired chemical integrity of the contact pad 142 may be preserved during the further processing of the device 100. Furthermore, a reliable confinement of the copper materials 122a, 123a of the metal regions 122, 123 is ensured by the conductive barrier materials 122b, 123b, 142b and by the dielectric silicon nitride-based layer 141a.

With reference to FIGS. 1f-1k further examples of a conventional process strategy will now be described in more detail wherein the number of lithography steps is reduced so as to provide for a more cost effective manufacturing process.

FIG. 1f schematically illustrates the device 100 basically in the same stage as shown in FIG. 1a. In this manufacturing stage, the complete passivation layer stack may be deposited on the basis of any well-established process techniques.

FIG. 1g schematically illustrates the device 100 with the passivation layer stack 140 formed above the metallization layer 120, wherein the layer stack comprises the copper-confining layer 141a followed by the silicon dioxide-based passivation layer 141b and the final nitride-based passivation layer 141c.

FIG. 1h schematically illustrates the device 100 with the etch mask 111 formed above the passivation layer stack 140 in order to define the lateral size and shape of an opening to be formed in the layer stack 140 in order to expose a portion of the metal region 122. Based on the etch mask 111 an appropriate etch sequence is applied so as to etch through the layer stack 140.

FIG. 1i schematically illustrates the device 100 in a further advanced manufacturing stage, i.e. after forming the contact pad 142 so as to be in direct contact with the metal region 122. To this end, a barrier material and an appropriate aluminum-based metal material is deposited, followed by a further lithography process for forming the etch mask 112. On the basis of a dedicated etch sequence exposed portions of the conductive materials are removed.

FIG. 1j schematically illustrates the device 100 after the removal of the etch mask 112. Consequently, the contact pad 142 and the patterning of the passivation layer stack is accomplished on the basis of two lithography steps, thereby contributing to a superior overall process flow. On the other hand, in particular the final etch process for patterning the contact pad 142 may result in a reduced thickness of the final passivation layer 141c.

FIG. 1k schematically illustrates an enlarged view of a portion of the device 100. As shown, a certain degree of recessing 140r is generated upon patterning the contact pad 142 in order to ensure a reliable removal of any conductive materials. Consequently, if a certain minimum remaining thickness for the layer 141c is required, an increased initial thickness may have to be provided or the etch time for patterning the contact pad 142 has to be reduced, thereby contributing to an increased probability of creating metallic residues. Furthermore, the contact pad 142 may be prone to mechanical damage upon the further processing of the device 100 due to the missing lateral enclosure by a passivation material, as is for instance the case in the device 100 when formed on the basis of the processes as described with reference to FIGS. 1a-1e.

Consequently, although the previously described approach may provide for superior mechanical integrity of the resulting contact pad, at least three lithography and patterning processes are involved, thereby rendering this approach less attractive in view of overall manufacturing costs. On the other hand, reducing the number of lithography processes, as in the latter process sequence, will result in degraded mechanical integrity and a higher probability of creating any leakage paths.

In view of this situation there is a need to provide semiconductor devices and manufacturing techniques in which contact pads may be formed above a copper-based metallization system while avoiding or at least reducing one or more of the problems identified above.

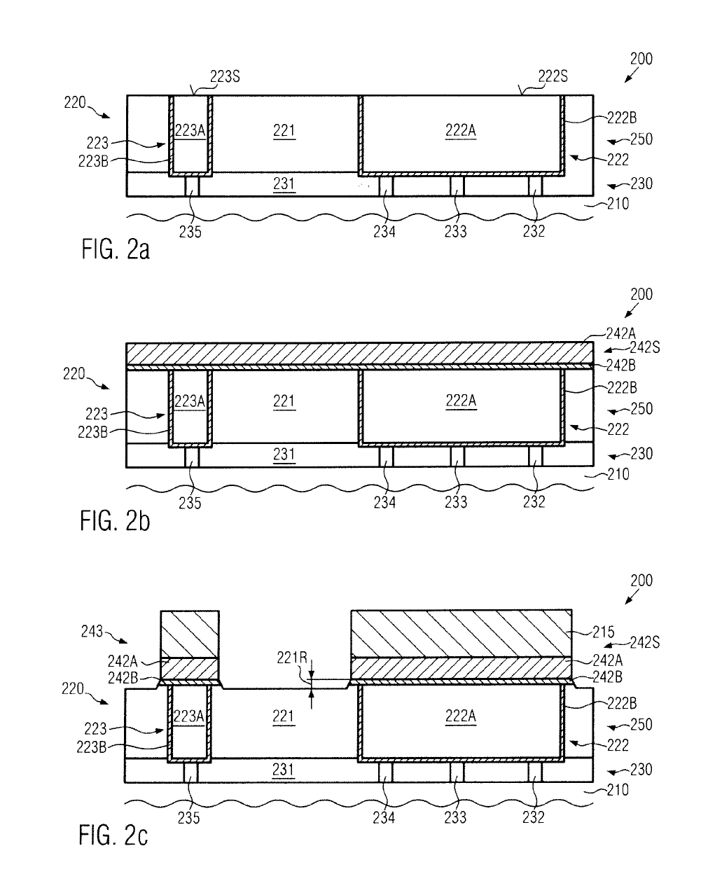

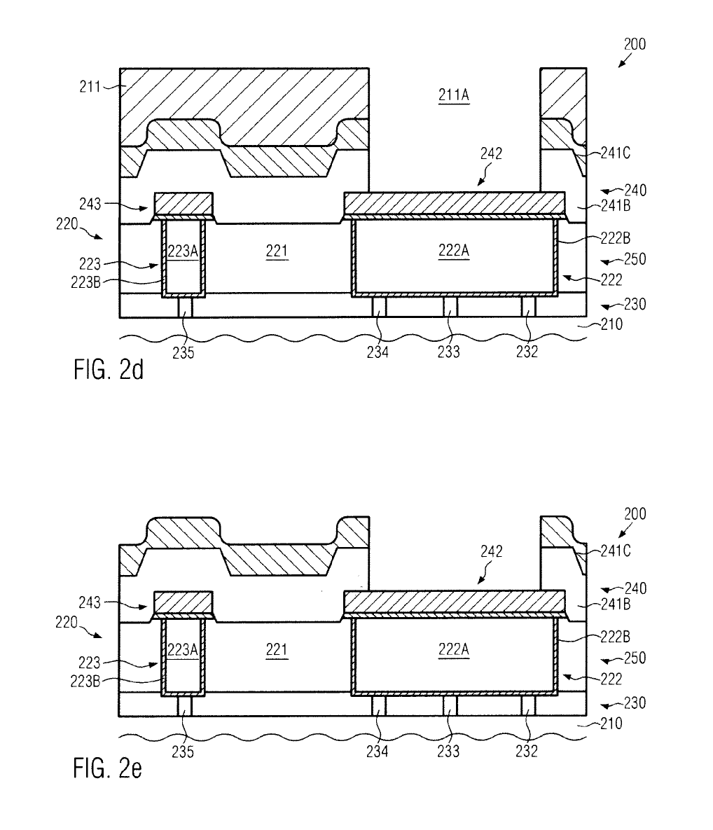

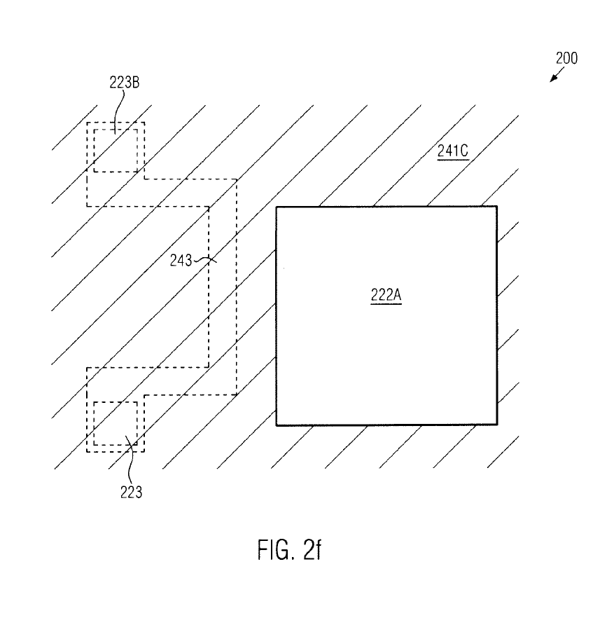

With reference to FIGS. 2a-2f further illustrative embodiments will now be described in more detail, wherein also reference may be made to FIGS. 1a-1k, if considered appropriate.

FIG. 2a schematically illustrates a cross-sectional view of a semiconductor device 200 comprising an appropriate carrier material 210, above which is formed a metallization system 250. As already discussed above with reference to the device 100, the carrier material 210 represents any appropriate material forming therein and thereabove semiconductor-based circuit elements as required for the functional behavior of the device 200. The metallization system 250 may be understood as a copper-based metallization system wherein at least a last metallization layer 220 comprises metal regions 222, 223 which include a significant amount of copper material. Moreover, the metallization layer 220 may be preceded by one or more further metallization layers wherein, for convenience, a single metallization layer 230 is illustrated, which represents a layer comprising a plurality of vertical contact elements 232, for instance comprising copper, tungsten or any other appropriate conductive material. It should be appreciated that further metallization layers including metal lines may be provided below the layer 230, depending on the overall complexity of the semiconductor device 200. The metallization layer 230 comprises a dielectric material 231, such as silicon dioxide, silicon nitride, a combination thereof, a low-k dielectric material, if considered appropriate, and the like. Similarly, the metallization layer 220 comprises a dielectric material 221 in the form of silicon dioxide, silicon nitride, a low-k dielectric material and the like. It should be appreciated that a low-k dielectric material is to be understood as a dielectric material having a dielectric constant of 3.0 or less. Using a low-k dielectric material in combination with a highly conductive copper material in one or more of the metallization layers of the system 250 may result in superior electrical performance. Moreover, the metal regions 222, 223 laterally embedded in the dielectric material 221 comprise a copper material 222a, for instance a substantially pure copper material or an alloy thereof, wherein the main portion may be provided in the form of copper. The corresponding fill materials are indicated as 222a, 223a, respectively. Furthermore, as discussed above, the copper-based materials 222a, 223a are separated from the surrounding dielectric material and the vertical contacts 232 by a barrier layer or layer system 223b, 222b, respectively. For example, well-established barrier materials such as tantalum nitride, tantalum, titanium, titanium nitride and the like, or any combination thereof, may be used. The device 200 as illustrated in FIG. 2a may be formed on the basis of process techniques as are also described above with reference to FIG. 1a when referring to the conventional semiconductor device 100. Consequently, after planarizing the surface of the metallization layer 220, the metal regions 222, 223 have exposed surface areas 222s, 223s, respectively.

FIG. 2b schematically illustrates the device 200 in a further advanced manufacturing stage. As shown, a cap metal layer system 242s is formed on the metallization layer 220 so as to be in direct contact with the metal regions 222, 223. In the embodiment shown, the system 242s comprises a conductive barrier material or material system 242b, for instance in the form of tantalum, tantalum nitride and the like and a metal layer 242a. In other cases, any other appropriate barrier materials, such as for more individual material layers of different composition, metal alloys and the like may be used. In some illustrative embodiments the system 242s is formed on the basis of well-established deposition techniques as are also used in conventional process strategies. In other illustrative embodiments (not shown) the conductive barrier material or material system 242b is formed on the basis of a selective deposition technique, for instance by applying electroless deposition techniques on the basis of appropriate electrolyte solutions, while the exposed surface areas 222s, 223s (cf. FIG. 2a) may act as appropriate catalyst materials. In this manner, any appropriate material composition, such as binary and ternary alloys including phosphorous, cobalt, nickel, molybdenum and the like, may be deposited in a highly selective manner, thereby providing for the desired degree of copper diffusion blocking capability and also forming a strong interface in order to reduce electromigration effects.

FIG. 2c schematically illustrates the device 200 in a further advanced manufacturing stage. As shown, an etch mask 215 such as a resist mask, a hard mask and the like is formed above the cap metal layer stack 242 so as to define the lateral position, size and shape of a cap metal layer stack to be formed above the metal regions 222, 223. For example, the mask 215 is appropriately patterned so as to ensure a reliable coverage of the metal regions 222, 223, which may be accomplished by providing a sufficient extra margin for any lateral dimensions of the mask 215 compared to the lateral dimensions of the metal regions 222, 223. The mask 215 is formed on the basis of a dedicated lithography mask and process. Thereafter, an appropriate etch process or process sequence is applied so as to remove the conductive material from between the metal regions 222, 223 in a reliable manner in order to avoid or reduce the probability of creating any leakage paths. To this end, an appropriate degree of recessing 221r may be applied, for instance by selecting an appropriate over-etch time or performing an additional final etch step. Since any passivation layer is still to be formed the patterning of a cap metal layer system into a contact pad 242 and a layer stack 243 does not influence the finally achieved passivation characteristics.

FIG. 2d schematically illustrates the device 200 in a further advanced manufacturing stage. As shown, a passivation layer stack 240 is formed above the metallization layer 220 and is appropriately patterned so as to expose at least a portion of the contact pad 242, while the cap metal layer stack 243 is covered by the passivation material 240. To this end, any appropriate material or material system may be deposited, for instance by plasma enhanced CVD and the like, wherein in some illustrative embodiments a first dielectric material 241b is deposited, for instance in the form of a silicon oxide-based material, followed by a second dielectric layer 241c such as a silicon nitride-based material. It should be appreciated that in the embodiment shown the deposition of a dedicated silicon nitride-based copper confining material is omitted since a reliable copper confinement of the regions 222, 223 is achieved by means of the contact pad 242 and the layer stack 243, which each comprise the barrier material 242b. Consequently, contrary to conventional strategies, the deposition of any such dedicated dielectric copper confining material can be omitted thereby contributing to a reduced process complexity. Moreover, superior electromigration behavior is imparted to any metal region formed in the metallization layer 220, in particular to the metal region 223, which is conventionally covered by the silicon nitride-based barrier material, which has been identified as a weak spot with respect to overall electromigration behavior.

The device 200 as shown in FIG. 2d may be formed by applying any appropriate deposition recipes for the passivation layer stack 240 followed by a further lithography step for forming the etch mask 211. Thereafter, an appropriate etch strategy is applied, for instance similar to conventional process strategies.

FIG. 2e schematically illustrates the device 200 after the removal of the etch mask 211 and any further manufacturing processes, such as cleaning processes and the like, if required. Consequently, the contact pad 242 and the patterning of the passivation layer stack 240 is accomplished on the basis of two lithography processes while nevertheless the contact pad 242 is laterally embedded in the passivation layer stack 240, thereby ensuring for superior mechanical integrity. Furthermore, an efficient copper confinement is achieved for any metal region, such as the region 223, on the basis of a conductive barrier material which may also contribute to enhanced electromigration behavior, as discussed above.

FIG. 2f schematically illustrates a top view of the semiconductor device 200 in a manufacturing stage that corresponds to the manufacturing stage as shown in FIG. 2e. Moreover, in the embodiment shown, the cap layer stack 243, which is formed above the metal region 223, is provided so as to form a metal-based circuit element, for instance in the form of a resistor, an electronic fuse that may be activated or “blown” on the basis of laser radiation, current flow and the like. Consequently, as shown, the circuit feature 243 is covered by the passivation material having the layer 241c as a final passivation material. On the other hand, a portion of the contact pad 242 is exposed. Consequently, by appropriately selecting the size and configuration of the cap layer stack 243 appropriate passive circuit elements may be formed together with a contact pad 242, without requiring any additional process steps. In the embodiment shown, the cap layer stack 243 represents a resistor, which is to be contacted by a further metal region 223b formed in the last metallization layer.

What is claimed is:

1. A method of forming a metallization system of a semiconductor device, comprising:
forming a cap metal layer system directly on an exposed surface of a metal region of a last metallization layer, said metal region comprising copper,
forming a contact pad from said cap metal layer system above said metal region,
forming a dielectric passivation layer above said last metallization layer and said contact pad, and
patterning said dielectric passivation layer so as to expose at least a portion of said contact pad.

2. The method of claim 1, wherein forming said cap metal layer system comprises forming at least one conductive barrier layer directly on said exposed surface of said metal region.

3. The method of claim 2, wherein forming said at least one conductive barrier layer comprises depositing a barrier material on said exposed surface and on a dielectric material of said metallization layer.

4. The method of claim 3, wherein forming said at least one conductive barrier layer comprises performing a selective electro-chemical deposition process.

5. The method of claim 1, further comprising forming a metal based circuit element from said cap layer system, wherein said circuit element is formed so as to be in contact with a second metal region formed in said last metallization layer.

6. The method of claim 1, wherein forming said cap metal layer system comprises depositing at least an aluminum comprising metal layer above said metallization layer so as to cover each metal region of said last metallization layer and removing any conductive material from above at least a portion of the dielectric material of said last metallization layer so as to laterally isolate said metal regions.

7. The method of claim 6, wherein removing any conductive material from above at least a portion of said dielectric material comprises performing an etch process and applying a specified over-etch time so as to etch into said dielectric material.

8. The method of claim 1, wherein forming said contact pad and exposing at least a portion thereof comprises performing two or less lithography processes.

9. The method of claim 1, wherein forming said cap layer system comprises forming a tantalum based barrier layer.

10. The method of claim 1, wherein forming a dielectric passivation layer above said last metallization layer comprises forming a silicon oxide based material on the dielectric material of said last metallization layer.

11. A semiconductor device, comprising:
a last metallization layer comprising an inter-metal dielectric material and a first metal region and a second metal region, said first and second metal regions comprising copper and being laterally embedded in said inter-metal dielectric material,
a first cap metal layer stack formed above said first metal region so as to be in direct contact with said first metal region,
a second cap metal layer stack formed above said second metal region so as to be in direct contact with said second metal region, and
a passivation layer stack formed laterally between said first and second cap metal layer stacks, said passivation layer stack covering said first metal region and exposing at least a portion of said second cap metal layer stack so as to form a contact pad.

12. The semiconductor device of claim 11, wherein said first and second cap metal layer stacks comprise at least one conductive copper-confining barrier layer.

13. The semiconductor device of claim 12, wherein said at least one conductive copper-confining barrier layer comprises tantalum and/or tantalum nitride.

14. The semiconductor device of claim 11, wherein said passivation layer stack comprises a silicon oxide based first layer that is directly formed on said inter-metal dielectric material of said last metallization layer.

15. The semiconductor device of claim 11, wherein said first cap metal layer stack is a passive circuit element.

16. The semiconductor device of claim 15, the passive circuit element is a fuse element.

17. A method of forming a metallization system of a semiconductor device, comprising:
forming a last metallization layer having a top surface and including a first copper metal region in a dielectric material;
forming a diffusion barrier on the top surface of the last metallization layer;
forming a metal layer on the diffusion barrier;
patterning the diffusion barrier and metal layer to form a contact pad over the copper metal region;
forming a passivation structure over the contact pad and last metallization layer; and
forming an opening in the passivation structure which exposes less than all of a top surface of the contact pad.

18. The method of claim 17, wherein forming the diffusion barrier on the top surface of the last metallization layer comprises forming a conductive barrier layer directly on an exposed surface of said first copper metal region.

19. The method of claim 17, wherein patterning the diffusion barrier and metal layer to form a contact pad over the copper metal region comprises etching through an opening in a mask to remove selected portions of the diffusion barrier and metal layer and over-etch into and remove an upper portion of the dielectric material in the last metallization layer.

20. The method of claim 17,
wherein the last metallization layer further includes a second copper metal region, further comprising:
patterning the diffusion barrier and metal layer to form a metal based circuit element over the second copper metal region; and
wherein forming the passivation structure further comprises forming the passivation structure over the metal based circuit element and last metallization layer.

21. The method of claim 20, wherein the metal based circuit element is a fuse element.

22. The method of claim 17, wherein forming the passivation structure over the contact pad and last metallization layer comprises forming a two layer passivation structure including a silicon nitride based material layer and a silicon oxide based material layer.
